(19) United States
(12) Patent Application Publication
(10) Pub. No.: US 2026/0011652 A1
(43) Pub. Date: Jan. 8, 2026

(54) REDUNDANT BOND PADS IN STACKED SEMICONDUCTOR ARCHITECTURES

(71) Applicant: Micron Technology, Inc., Boise, ID (US)

(72) Inventors: Bharat Bhushan, Boise, ID (US); Kunal R. Parekh, Boise, ID (US); Lars P. Heineck, Boise, ID (US); Akshay N. Singh, Boise, ID (US)

(21) Appl. No.: 19/255,700

(22) Filed: Jun. 30, 2025

Related U.S. Application Data
(60) Provisional application No. 63/667,629, filed on Jul. 3, 2024.

(51) Int. Cl. H01L 23/538; H01L 23/00; H01L 25/04

(52) U.S. Cl. CPC H01L 23/5386; H01L 24/02; H01L 24/03; H01L 24/08; H01L 24/80; H01L 25/04; H01L 2224/0231; H01L 2224/02371; H01L 2224/08145; H01L 2224/80895; H01L 2225/06541

(57) ABSTRACT

Methods, systems, and devices for redundant bond pads in stacked semiconductor architectures are described. A semiconductor device may be formed one or more redundant structures. A memory chip and a logic die may be formed with a redistribution layer that interconnects multiple bonding pads together. The redistribution layer may couple the bonding pads with a common via, where the common via interfaces with circuitry of a respective device. Additionally, or alternatively, a memory chip and a logic die may be formed with redundant via paths that form parallel electrical paths. The redundant via paths may couple device circuitry with respective bonding pads of a device. The memory chip and the logic die may be bonded together to form a semiconductor device.

### CROSS REFERENCE

The present Application for Patent claims priority to U.S. Patent Application No. 63/667,629 by Bhushan et al., entitled “REDUNDANT BOND PADS IN STACKED SEMICONDUCTOR ARCHITECTURES,” filed Jul. 3, 2024, which is assigned to the assignee hereof, and which is expressly incorporated by reference in its entirety herein.

### TECHNICAL FIELD

The following relates to one or more semiconductor systems, including redundant bond pads in stacked semiconductor architectures.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

In some cases, techniques for manufacturing memory devices (e.g., or other semiconductor devices) may include manufacturing operations that produce debris. Such debris may affect bonding operations between various components of a memory device.

### BRIEF DESCRIPTION OF THE DRAWINGS

FIG. 1 shows an example of a system that supports redundant bond pads in stacked semiconductor architectures in accordance with examples as disclosed herein.

FIG. 2 shows an example of a system that supports redundant bond pads in stacked semiconductor architectures in accordance with examples as disclosed herein.

FIG. 3 shows an example of architectures that support redundant bond pads in stacked semiconductor architectures in accordance with examples as disclosed herein.

FIGS. 4 through 9 show example operations for forming a semiconductor device that supports redundant bond pads in stacked semiconductor architectures in accordance with examples as disclosed herein.

FIGS. 10 and 11 show flowcharts illustrating a method or methods that support redundant bond pads in stacked semiconductor architectures in accordance with examples as disclosed herein.

### DETAILED DESCRIPTION

Some semiconductor systems (e.g., memory systems, processor systems) may include a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. The HBM system may be in communication with a processor, such as GPU or other host device, through an interposer. Such configuration may be known as 2.5D configuration. In some examples, a 3D stacked memory system may be closely coupled (e.g., physically coupled, electrically coupled, directly coupled) with a processor, such as a GPU or other host device, as part of a physical memory map accessible to the processor. Such configuration may be known as 3D configuration. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Some semiconductor systems, such as a semiconductor device including one or more memory chips (e.g., dynamic random access memory (DRAM) chips, stacks of DRAM chips, memory dies, 3D stacked memory devices), one or more logic dies (e.g., logic blocks, memory interface blocks), and other components (e.g., host devices) may be manufactured using various manufacturing operations. In some cases, at least some manufacturing operations may produce debris, such as material fragments and various residues, which may adversely affect a production (e.g., a manufacturing yield) of such semiconductor systems. For instance, operations such as dicing (e.g., removing material by cutting or grinding), adhering (e.g., gluing, taping), separating (e.g., de-taping) may result in material particles, adhesive residues, and other debris, which may contaminate components of the semiconductor system. In some cases, the debris may collect on one or more bonding pads (e.g., pads formed of a conductive material for bonding various system components together) prior to performing a bond with other components (e.g., dies, wafers, devices). Accordingly, when performing the bond, the debris may cause a connection between bonding pads to be faulty (e.g., may at least partially inhibit an electrical connection of the bond), and the semiconductor device may fail to satisfy a performance evaluation based on the faulty bond. Thus, the semiconductor device may be rejected (e.g., discarded) resulting in reduced manufacturing yield. Such rejections are particularly exaggerated in some techniques, such as when pad pitches are scaled down (e.g., to less than 10 microns).

In accordance with one or more techniques described herein, a semiconductor device (e.g., an HBM system, a 3D stacked memory system, a heterogeneous semiconductor device) may be formed (e.g., manufactured) with one or more redundant structures to improve the reliability of the semiconductor device. In some examples, a memory chip (e.g., a 3D stacked memory chip, a memory array die), a logic die, or other device (e.g., a host device) may be formed with a routing layer (e.g., redistribution layer (RDL), backend of line (BEOL) layers), which may interconnect several bonding pads together and couple the bonding pads with a common via (e.g., a through-oxide via (TOV), a through-silicon via (TSV)) that interfaces with (e.g., is coupled with) device circuitry. Additionally, or alternatively, a memory chip, a logic die, or other device may be formed with redundant via paths (e.g., redundant TOVs, redundant TSVs). For instance, multiple vias may form parallel electrical paths (e.g., may be coupled with the same device circuitry) and may be coupled with respective bonding pads of a device. Accordingly, if a bond between devices is faulty (e.g., due to manufacturing debris), the redundant structures may provide an alternate (e.g., redundant) electrical path to compensate for the failed bond and may enable a semiconductor device to successfully satisfy a performance evaluation. In some examples, one device having one or more redundant structures may be coupled with another device having redundant structures that mirror the redundant structure of the device. Additionally, the redundant structures may reduce an electrical resistance of the bonds, which may further improve a reliability of the bonded connection. Thus, semiconductor devices may be manufactured with increased efficiency and improved reliability, resulting in relatively more devices satisfying a performance evaluation and improving manufacturing yield.

In addition to applicability in memory systems as described herein, techniques for redundant bond pads in stacked semiconductor architectures may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by including redundancies in the bonding structure, which may improve manufacturing yield and improve device reliability thereby reducing electronic waste and extending the life of electronic devices, among other benefits.

Features of the disclosure are illustrated and described in the context of systems and architectures. Features of the disclosure are further illustrated and described in the context of illustrative operations for semiconductor device formation and flowcharts.

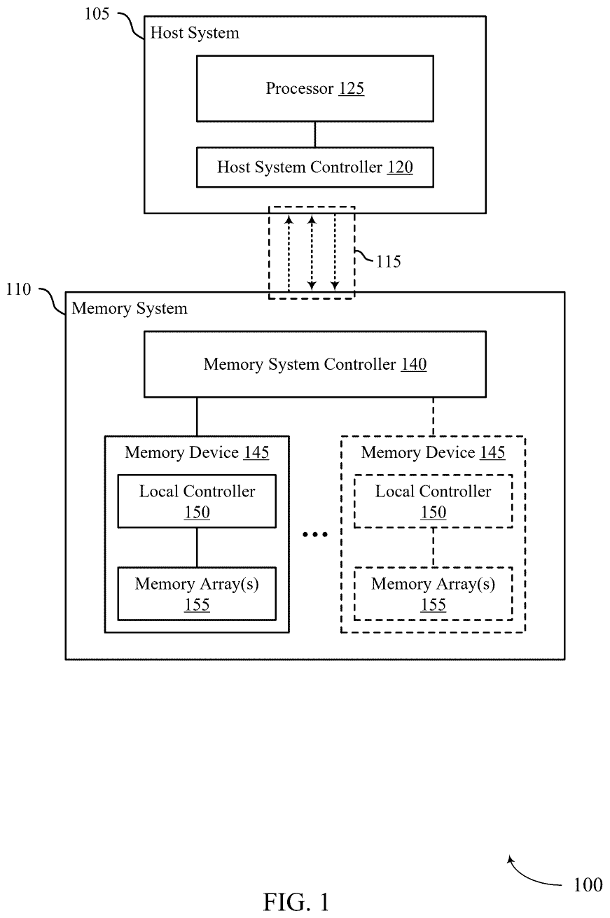

FIG. 1 shows an example of a system 100 that supports redundant bond pads in stacked semiconductor architectures in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a GPU, a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies. In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a 3D stacked memory system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

Some systems 100 may be manufactured using various manufacturing operations that produce debris, such as material particles and residues, that adversely affects a production (e.g., a manufacturing yield) of such systems 100. For instance, the debris may collect on bonding pads resulting in a faulty connection between bonding pads and reducing manufacturing yield. In accordance with one or more techniques described herein, a system 100, or a portion thereof, may be formed with one or more redundant structures to improve a reliability of bonding operations. In some examples, a memory device 145 (e.g., a 3D stacked memory chip, a memory array die, a memory chip, a memory system 110), a logic die, or other devices (e.g., a host system 105) may be formed with a routing layer (e.g., RDL or BEOL layer) that couples several bonding pads with a common via that is coupled with device circuitry. Additionally, or alternatively, a memory device 145, a logic die, or other device may be formed with redundant via paths (e.g., redundant TOVs, redundant TSVs). Accordingly, the redundant structures may improve a likelihood that the system 100 satisfies a performance evaluation procedure and may further improve reliability of the system 100. Such techniques may improve a manufacturing yield of semiconductor devices by reducing a quantity of rejected dies in a manufacturing process.

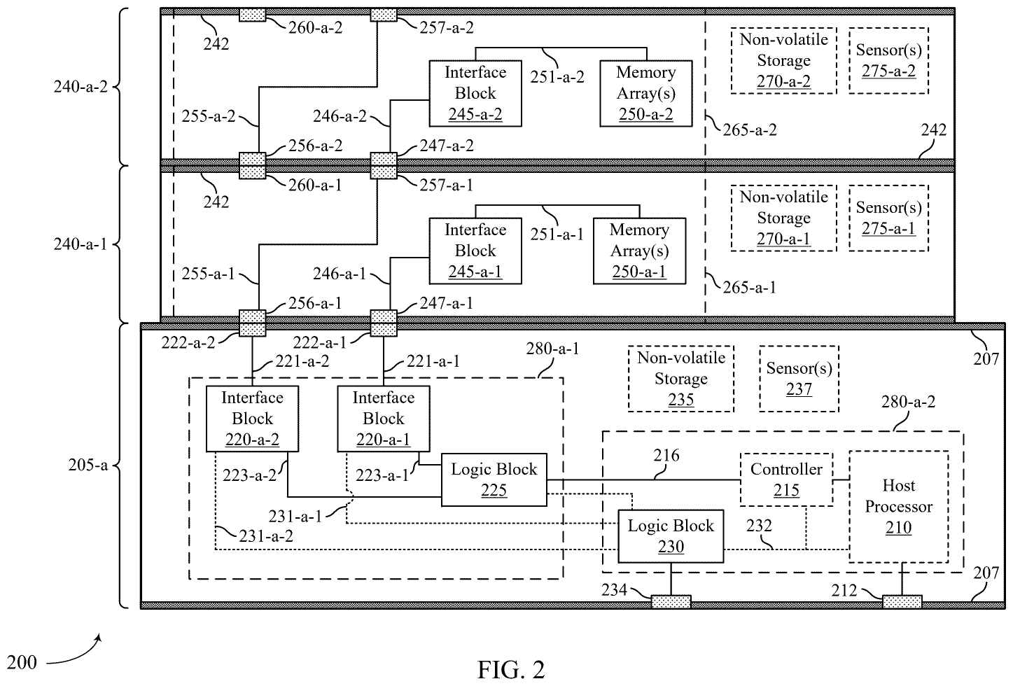

FIG. 2 shows an example of a system 200 (e.g., a semiconductor system, a system of coupled semiconductor dies, an HBM system, a 3D stacked memory system) that supports redundant bond pads in stacked semiconductor architectures in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory implementations), a die 205 may include a host processor 210. A host processor 210 may be an example of a host system 105, or a portion thereof (e.g., a processor 125, aspects of a host system controller 120, or both). The host processor 210 may be configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation) (e.g., in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 die and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various

techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube” or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

Some systems 200 may be manufactured using various manufacturing operations that produce debris, such as material particles and residues, that adversely affects a production (e.g., a manufacturing yield) of such systems 200. For instance, the debris may collect on bonding pads resulting in a faulty connection between bonding pads (e.g., contacts 212, 222, 234, 247, 256, 257, 260) and reducing manufacturing yield. In accordance with one or more techniques described herein, a system 200, or a portion thereof, may be formed with one or more redundant structures to improve a reliability of bonding operations. In some examples, a die 240 (e.g., a 3D stacked memory chip, a memory array die, a memory chip, a memory system 110), a die 205 (e.g., a logic die), or other devices (e.g., a host die) may be formed with an RDL that couples several bonding pads with a common via that is coupled with device circuitry (e.g., internal component of the dies 240 and/or the die 205). Additionally, or alternatively, a die 240, a die 205, or other device may be formed with redundant via paths (e.g., redundant TOVs, redundant TSVs). Accordingly, the redundant structures may improve a likelihood that the system 200 satisfies a performance evaluation procedure and may further improve reliability of the system 200. Such techniques may improve a manufacturing yield of semiconductor devices by reducing a quantity of rejected dies in a manufacturing process.

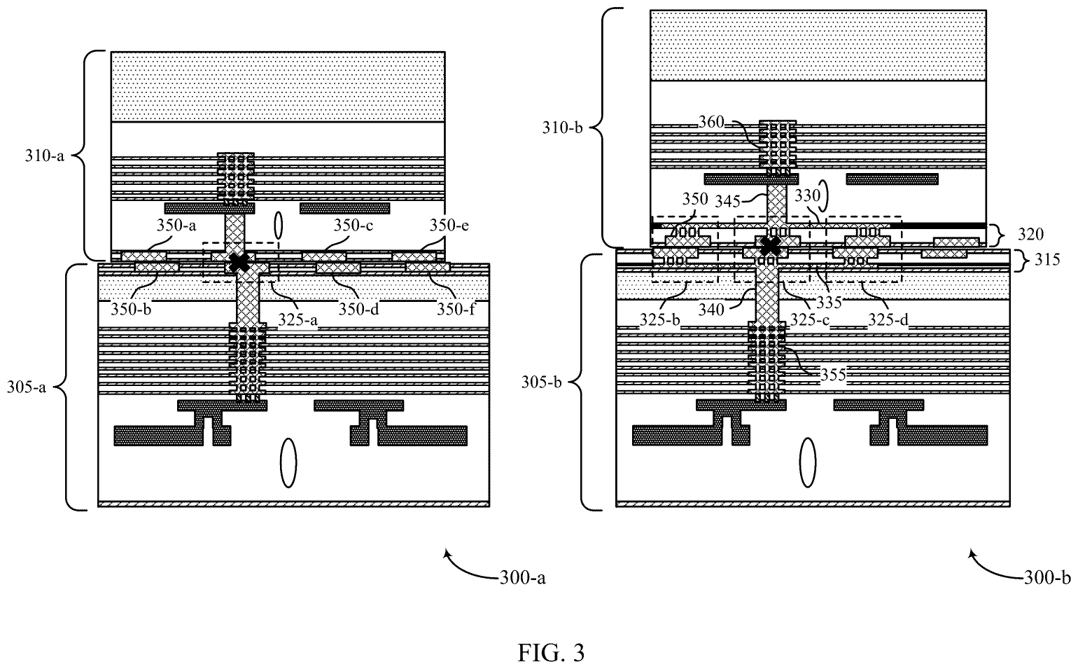

FIG. 3 shows an example of an architecture 300-a and an architecture 300-b that supports redundant bond pads in stacked semiconductor architectures in accordance with examples as disclosed herein. The architectures 300 may include respective dies 305 (e.g., logic dies) and memory chips 310 (e.g., individual memory dies cut from a wafer of memory dies). The dies 305 and the memory chips 310 may be examples of or include a die 205 and a die 240 respectively. Each die 305 may be coupled with a memory chip 310 based on one or more conductive pads 350 (e.g., bond pads, hybrid bond pads). That is, one or more conductive pads 350-a may be bonded with respective one or more conductive pads 350-b as part of a bonding operation, such as hybrid bonding. In some cases, “hybrid bonding” may refer to a method used in bonding processes (e.g., chip-to-wafer (C2W) or wafer-to-wafer (W2W) bonding) that combines various bonding mechanisms such as metallic bonding and dielectric bonding. For instance, the surfaces of the components to be bonded (e.g., two wafers or a chip and a wafer, the die 305 and the memory chip 310) may include areas of conductive material (e.g., the conductive pads 350) and dielectric material (e.g., material in between the conductive pads 350) that are bonded together (e.g., simultaneously) as part of a hybrid bonding process. In some cases, a conductive pad 350 (e.g., and other similar structures herein) may be described as a “hybrid bond pad,” which may refer to an area of conductive material (e.g., copper) that supports bonding with another area of conductive material (e.g., supports metal-to-metal connections).

In some cases, a die 305 may be part of a wafer that includes multiple dies 305. A memory chip 310 may have previously been diced (e.g., cut) from a wafer of multiple memory chips 310. Accordingly, the bonding between the dies 305 and the memory chips 310 may include a C2W bond between an individual memory chip 310 and a respective die 305 of the wafer of dies 305. Although various examples herein may be described within the context of such C2W bonding, the disclosed techniques may apply for other bonding scenarios, such as W2W bonding (e.g., a wafer of memory chips 310 being bonding with a wafer of dies 305) or other C2W bonding configurations (e.g., a wafer of memory chips 310 being bonded with a diced die 305).

Some semiconductor devices may support the architecture 300-a and may be manufactured using various manufacturing operations that may produce debris particles, such as material fragments and various residues (e.g., dicing particles, de-tape residues, adhesive glue residues). Such debris may adversely affect a bond between dies 305 and memory chips 310. For instance, operations such as dicing, etching, cutting, adhering, and separating may produce material dust, adhesive residues, and other debris, which may collect on the conductive pads 350 prior to a bonding operation. In some cases, one or more conductive pads 350 may be formed as redundant pads (e.g., dummy pads) during a manufacturing operation. For instance, a device may be formed with redundant conductive pads 350, such as conductive pads 350-a, 350-b, 350-c, 350-d, 350-e, and 350-f, that are not coupled with internal circuitry of the device. Such redundant pads may be formed to maintain uniformity (e.g., based on a patterning of the manufacturing operation) or to increase mechanical support of the bond between devices, among other purposes. In the example of the architecture 300-a, debris may have collected on the conductive pads 350 (e.g., dummy pads) of the die 305-a and/or the memory chip 310-a. During a subsequent bonding operation, a bond 325-a between respective conductive pads 350 may be faulty (e.g., an electrical connection between the respective conductive pads 350 may be at least partially impeded) and the architecture 300-a may not satisfy a performance evaluation (e.g., may fail one or more test procedures) based on the faulty bond 325-a. Accordingly, a semiconductor device that includes the architecture 300-a may be discarded, thus reducing manufacturing yield and increasing waste.

Some examples and operations described herein may be described with reference to various sides of a respective component (e.g., a die 305, a memory chip 310). For example, a side of a component may be referred to as a “backside” or a “frontside.” A frontside of a semiconductor device may refer to a side that includes components such as transistors and capacitors. The frontside may also include an electrically conductive metallization structure with chip contact areas. The frontside may include frontend of line (FEOL), middle of line (MOL), and BEOL layers. The frontside may face up during the manufacturing process and may be the primary surface for the device's operation. On the other hand, a backside of a semiconductor device may refer to a side that is opposite to where the main functional elements are located. The backside may be used for various supporting functions that complement the frontside. In some examples, the frontside may be opposite a substrate material on which the device was formed (e.g., opposite of a backside). In some examples, the backside may be a same side as a substrate material (e.g., a silicon substrate) on which the component was formed (e.g., a substrate for mechanical support during formation). For example, in some implementations, a backside of the die 305 may be bonded with a frontside of a memory chip 310.

In accordance with one or more techniques described herein, a semiconductor device may be formed with one or more redundant structures to improve a reliability of one or more bond between dies (e.g., or chips) of the semiconductor device. In some examples, a semiconductor device may support the architecture 300-b that includes a die 305-b and a memory chip 310-b. The die 305-b may be formed with a layer 315 (e.g., one or more dielectric materials, on a backside of the die 305-b) including an RDL 335 coupled with multiple conductive pads 350 (e.g., two or more functional conductive pads) of the die 305-b. In some examples, an “RDL” may refer to one or more layers of conductive material (e.g., copper, aluminum) that is used to route a layout of one or more interface nodes (e.g., inputs, outputs) of a component (e.g., the die 305, the memory chip 310). The RDL 335 may couple the conductive pads 350 with a via 340 that is associated with circuitry 355. The memory chip 310-b may be formed with a layer 320 (e.g., one or more dielectric materials, on a front side of the memory chip 310-b) including an RDL 330 coupled with multiple conductive pads 350 (e.g., two or more, functional conductive pads) of the memory chip 310-b. The RDL 330 may couple the conductive pads 350 with a via 345 that is associated with circuitry 360. Accordingly, the architecture 300-b may support various electrical paths between the die 305-b and the memory chip 310-b thereby improving a likelihood that a semiconductor device will satisfy a performance evaluation. For example, debris particles may cause a bond 325-c to be faulty. However, a bond 325-b and/or a bond 325-d may not be faulty, and thus, a reliable connection between the die 305-b and the memory chip 310-b may be maintained.

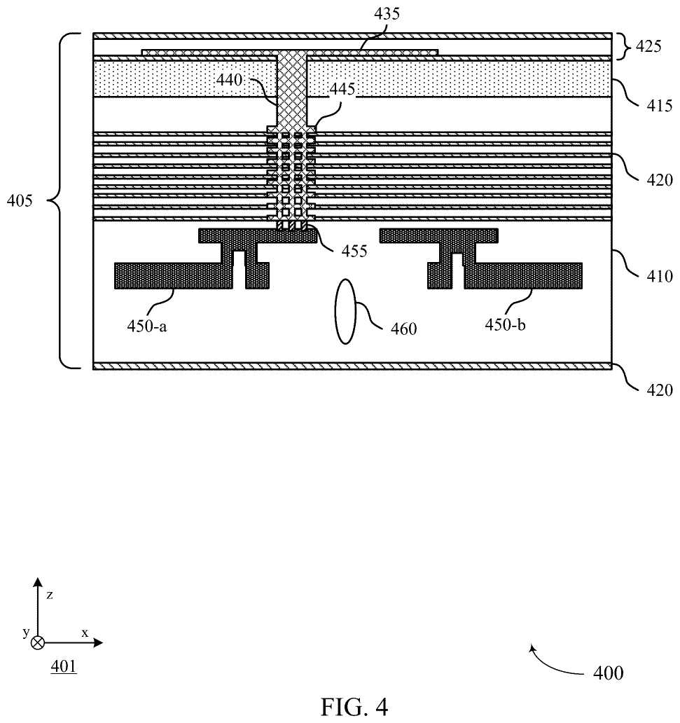

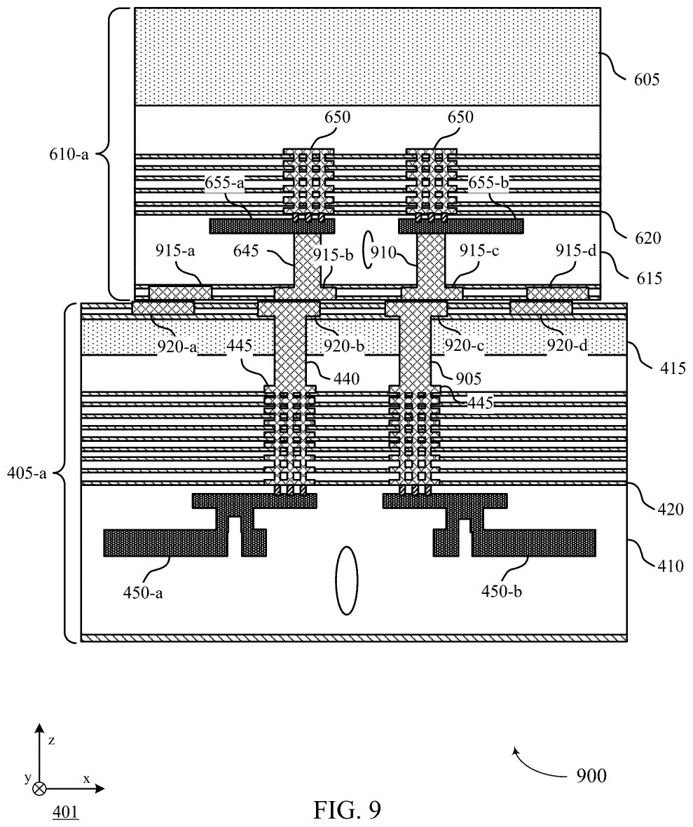

The formation of the architecture 300-b (e.g., with redundant functional conductive pads 350 and respective RDLs) may be described in greater detail herein, including with reference to FIGS. 4 through 8. In some additional, or alternative, cases, a die 305 and a memory chip 310 (e.g., or other device) may be formed with redundant via paths (e.g., additional TOVs, additional TSVs) (not shown). For instance, a die 305 may include multiple vias 340 and a memory chip 310-b may include multiple vias 345, each coupled with respective conductive pads 350. The multiple vias 340 and 345 may be form parallel electrical paths between the dies 305 and the memory chips 310. Thus, if one via path fails (e.g., due to a bonding failure), a redundant via path may compensate for the failure and the semiconductor device may successfully satisfy a performance evaluation. Such examples of redundant via paths may be described in greater detail herein, including with reference to FIG. 9.

Accordingly, the redundant structures described herein may provide an alternate electrical path to increase the reliability of bonds 325 (e.g., C2W bonds) between conductive pads 350. That is, the described techniques may repurpose one or more redundant conductive pads 350 (e.g., conductive pads 350-a through 350-f, existing functional pads) to support various alternative electrical paths between respective circuitry of multiple devices, thereby increasing reliability based on the redundant bonds. Additionally, the redundant structures may reduce a resistance (e.g., a current density) of the bonded connections between pads 350, further improving reliability of the bonded connection. Moreover, the techniques herein may enable a combination of active pads that are electrically coupled with one another as well as functional pads (e.g., as opposed to having separate active pads and functional pads). Thus, semiconductor devices may be manufactured with increased reliability, resulting in relatively more devices satisfying a performance evaluation and thereby improving manufacturing yield.

FIGS. 4 through 9 illustrate examples of operations for forming a semiconductor device 400 (e.g., a heterogeneous device, a semiconductor system of heterogeneous dies, a heterogeneous HBM system, a heterogeneous 3D stacked memory system) utilizing redundant bond pads in stacked semiconductor architectures in accordance with examples as disclosed herein. For example, FIGS. 4 through 9 may illustrate aspects of a sequence of operations that may support manufacturing a system 100 or a portion thereof, a system 200 or a portion thereof, or some other device herein, which may increase device yield during manufacturing and improve device reliability. Each of the figures may be described with reference to an x-direction, a y-direction, and a z-direction of the coordinate system 401. Operations illustrated in and described with reference to FIGS. 4 through 9 may be performed by a manufacturing system, such as a semiconductor fabrication system configured to perform additive operations (e.g., deposition, epitaxy, bonding, adhering), subtractive operations (e.g., etching, trenching, planarizing, polishing, dicing, cutting, separating), modifying operations (e.g., oxidizing, doping, reacting, converting), and supporting operations (e.g., masking, patterning, photolithography, aligning), among other operations that support the described techniques. In some examples, portions of the semiconductor device 400 that are illustrated with a same pattern may be formed of same or similar materials and portions that are illustrated with different patterns may be formed of different materials.

FIG. 4 shows an example of a portion of a semiconductor device 400 after a first set of one or more manufacturing operations. For example, the first set of operations may include forming a die 405 (e.g., a logic die, an interface block, a die 205, a die 305, foundry logic). The die 405 may include various layers of one or more dielectric materials 410 (e.g., silicon oxide) and one or more dielectric materials 420 (e.g., silicon carbon nitrate). The die may further be formed on a substrate material 415 (e.g., a silicon substrate). In some examples, the substrate material 415 may be part of a wafer silicon substrate. That is, the die 405 may be part of a wafer that includes multiple dies 405 (not shown). In some examples, the one or more dielectric materials 410, the one or more dielectric materials 420, and/or the substrate material 415 may include transistor circuitry (e.g., complementary metal-oxide-semiconductor (CMOS) circuitry) associated with operating the die 405. In some examples, the die 405 may also be associated with (e.g., formed on) a carrier substrate (not shown), which may be formed on a side that is opposite the substrate material 415.

The die 405 may be formed with at least one via 440. The via 440 may be coupled with circuitry 445 (e.g., BEOL circuitry, interconnection circuitry, logic circuitry, formed as part of the first set of operations) of the die 405. The first set of operations may further include forming an RDL 435 in a layer 425 (e.g., including one or more dielectric materials 410 and one or more dielectric materials 420) of the die 405. The RDL 435 may support connections with multiple conductive pads (e.g., functional pads, hybrid bond pads). The RDL 435 may be formed on a same side of the die 405 as the substrate material 415 (e.g., a backside of the die 405, a backside RDL). The RDL 435, the via 440, and the circuitry 445 may be formed of one or more conductive materials (e.g., copper). The via 440 may extend from the RDL 435 through (e.g., along a z-direction) the substrate material 415 (e.g., a silicon material) of the die (e.g., the via 440 may be a TSV) and may couple with the circuitry 445.

The die 405 may be also formed with one or more RDL materials 450 (e.g., an inline RDL (iRDL), RDL materials 450-a, RDL materials 450-b, aluminum materials) within the die 405. The via 440 may be coupled with one or more RDL materials 450 (e.g., the RDL materials 450-a) within the die 405 based on the circuitry 445 of the die 405. In some examples, the circuitry 445 may be coupled with the RDL materials 450 based on one or more contacts 455 (e.g., formed of a tungsten material). In some examples, one or more operations of the first set of operations may result in an airgap 460 within the one or more dielectric materials 410.

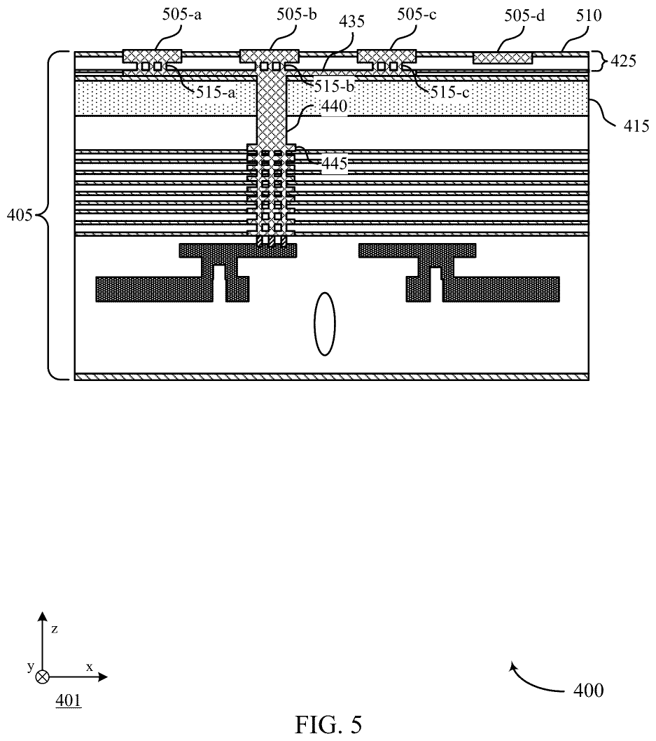

FIG. 5 shows an example of a portion of a semiconductor device 400 after a second set of one or more manufacturing operations. For example, the second set of operations may include forming multiple (e.g., two or more) conductive pads 505 (e.g., functional conductive pads, hybrid bond pads) over (e.g., or in) the layer 425 (e.g., a dielectric layer) of the die 405. In some examples, the conductive pads 505 may be formed on a surface 510 of the die 405 (e.g., same side of the die 405 as the substrate material 415, a backside of the die 405). In some examples, the conductive pads 505 may be directly coupled with the RDL 435. Alternatively, the conductive pads 505 may be coupled with the RDL 435 based on one or more vias 515 (e.g., formed of a conductive material, such as copper). For example, the second set of operations may include forming multiple vias 515 (e.g., which may be relatively smaller than the via 440) in the layer 425 that is positioned over the RDL 435. In such examples, each conductive pads 505 may be coupled with a respective subset of vias 515 (e.g., pad 505-a may be coupled with vias 515-a, pad 505-b may be coupled with vias 515-b, pad 505-c may be coupled with vias 515-c, and so on). Accordingly, the conductive pads 505 may be coupled with the RDL 435 based on the vias 515, and the conductive pads 505 may be coupled with the via 440 based on the RDL 435. In some examples, the RDL 435 may repurpose one or more redundant conductive pads 505 (e.g., pad 505-a and pad 505-c) to support an alternate electrical path to the via 440 and the circuitry 445.

Although FIG. 5 illustrates a non-limiting example including three pads 505 coupled with the RDL 435 and the via 440, the second set of operations may include formation of more pads 505 (e.g., four or more pads 505 per via 440) or fewer pads 505 (e.g., two pads 505 per via 440) that are coupled with the RDL 435 than shown. In some examples, a quantity of pads 505 may be based on a density metric associated with the via 440 and/or the pads 505. For example, a first density metric associated with the via 440 may be relatively smaller than a second dentistry metric associated with the conductive pads 505. Additionally, the die 405 may include at least some conductive pads 505 that are not coupled with the RDL 435 (e.g., conductive pad 505-d).

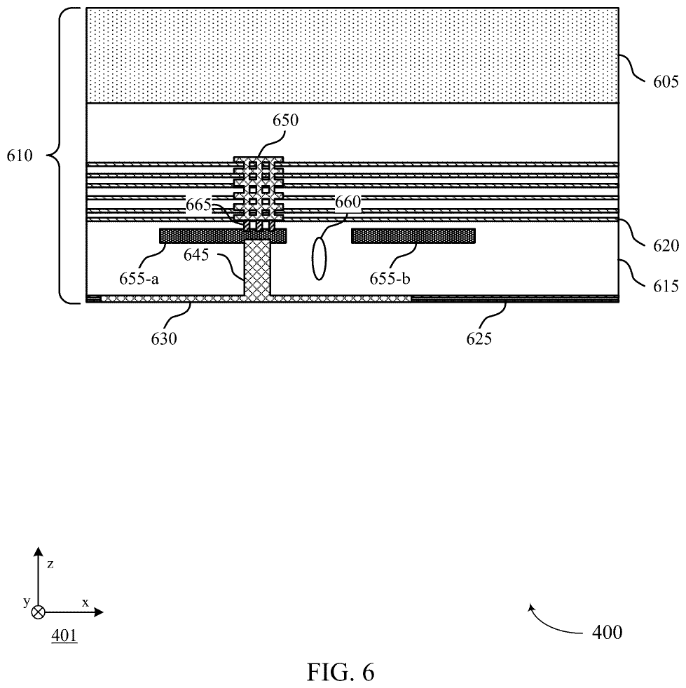

FIG. 6 shows an example of a portion of a semiconductor device 400 after a third set of one or more manufacturing operations. For example, the third set of operations may include forming a memory chip 610 (e.g., a 3D stacked memory chip, a DRAM device, a memory device 145, a die 240, a memory chip 310). The memory chip 610 may include various layers of one or more dielectric materials 615 (e.g., silicon oxide) and one or more dielectric materials 620 (e.g., silicon carbon nitrate). The die may further be formed on a substrate material 605 (e.g., a silicon substrate). In some examples, the substrate material 605 may be part of a wafer silicon substrate (e.g., at the third set of operations). That is, the memory chip 610 may be part of a wafer that includes multiple memory chips 610 (not shown). In some examples, the one or more dielectric materials 615, the one or more dielectric materials 620, and/or the substrate material 605 may include transistor circuitry (e.g., complementary metal-oxide-semiconductor (CMOS) circuitry) associated with operating the memory chip 610.

The memory chip 610 may be formed with at least one via 645. The via 645 may be coupled with circuitry 650 (e.g., BEOL circuitry, interconnection circuitry, memory array circuitry, formed as part of the third set of operations) of the memory chip 610. In some examples, circuitry 650 may be associated with performing one or more access operations at the memory device (e.g., of one or more memory arrays included in the memory chip 610). The third set of operations may further include forming an RDL 630 in the memory chip 610. In some examples, the RDL 630 may be formed on a surface 625 of the die 405 that is opposite the substrate material 605 of the memory chip 610 (e.g., a frontside of the memory chip 610, a frontside RDL). The RDL 630 may support connections with multiple conductive pads (e.g., functional pads, hybrid bond pads). The RDL 630, the via 645, and the circuitry 650 may be formed of one or more conductive materials (e.g., copper).

The via 645 may extend from the RDL 630 through (e.g., along a z-direction) the one or more dielectric materials 615 (e.g., an oxide material) of the memory chip 610 (e.g., the via 645 may be a TOV) and may couple with the circuitry 650. In some examples, the third set of operations may further include forming one or more aluminum contacts 655 (e.g., the aluminum contacts 655-a and 655-b, or a contact formed of other conductive material), and the via 645 may be coupled with the circuitry 650 based on an aluminum contact 655 associated with the circuitry 650 (e.g., the aluminum contacts 655-a). In some examples, the aluminum contacts 655 may be coupled with the circuitry 650 based on one or more contacts 665 (e.g., formed of a tungsten material). In some examples, one or more operations of the third set of operations may result in an airgap 660 within the one or more dielectric materials 615.

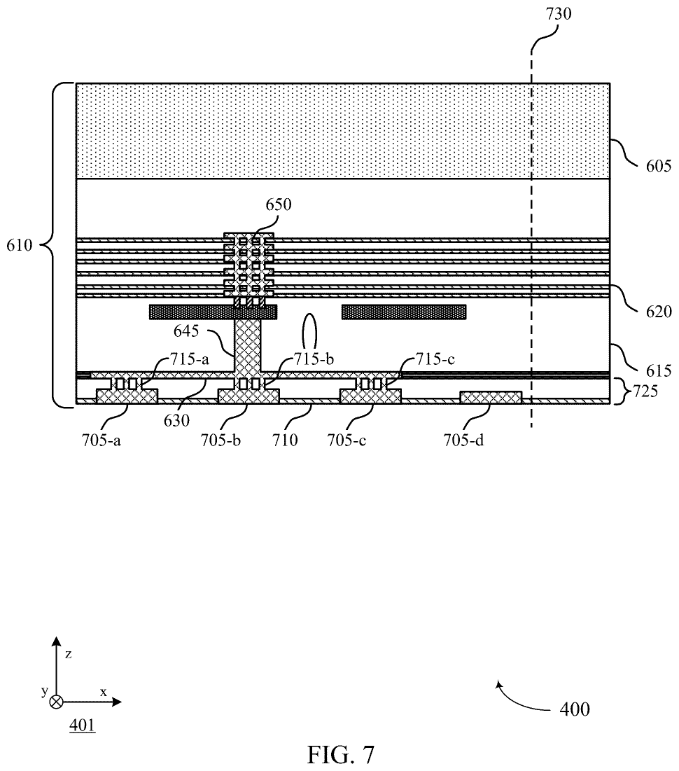

FIG. 7 shows an example of a portion of a semiconductor device 400 after a fourth set of one or more manufacturing operations. For example, the fourth set of operations may include forming multiple (e.g., two or more) conductive pads 705 (e.g., functional conductive pads, hybrid bond pads) over (e.g., or in) the layer 725 (e.g., a dielectric layer) of the memory chip 610. In some examples, the conductive pads 705 may be formed on a surface 710 of the memory chip 610 (e.g., a side of the memory chip 610 that is opposite the substrate material 605, a frontside of the memory chip 610). In some examples, the conductive pads 705 may be directly coupled with the RDL 630. Alternatively, the conductive pads 705 may be coupled with the RDL 630 based on one or more vias 715 (e.g., formed of a conductive material, such as copper). For example, the fourth set of operations may include forming multiple vias 715 (e.g., which may be relatively smaller than the via 645) in the layer 725 that is positioned over the RDL 630. In such examples, each conductive pads 705 may be coupled with a respective subset of vias 715 (e.g., pad 705-a may be coupled with vias 715-a, pad 705-b may be coupled with vias 715-b, pad 705-c may be coupled with vias 715-c, and so on). Accordingly, the conductive pads 705 may be coupled with the RDL 630 based on the vias 715, and the conductive pads 705 may be coupled with the via 645 based on the RDL 630. In some examples, the RDL 630 may repurpose one or more redundant conductive pads 705 (e.g., pad 705-a and pad 705-c) to support an alternate electrical path to the via 645 and the circuitry 650.

In some examples, the fourth set of operations may include dicing, after forming the RDL 630, the memory chip 610 from a wafer that includes multiple memory chips 610 (not shown). That is, the memory chip 610 may be diced along a boundary 730 as part of the fourth set of operations such that a portion of the memory chip 610 (e.g., the materials to the right of the boundary 730) may be removed after the fourth set of operations. After the dicing, the substrate material 605 may be referred to as “chip silicon,” and the memory chip 610 may be ready for bonding procedures (e.g., a C2W bonding). In some examples (e.g., W2W bonding), the memory chip 610 may not be diced from a wafer prior to bonding with other devices.

Although FIG. 7 illustrates a non-limiting example including three pads 705 coupled with the RDL 630 and the via 645, the fourth set of operations may include formation of more pads 705 (e.g., four or more pads 705 per via 645) or fewer pads 705 (e.g., two pads 705 per via 645) that are coupled with the RDL 630 than shown. In some examples, a quantity of pads 705 may be based on a density metric associated with the via 645 and/or the pads 705. For example, a first density metric associated with the via 645 may be relatively smaller than a second dentistry metric associated with the conductive pads 705. Additionally, the memory chip 610 may include at least some conductive pads 705 that are not coupled with the RDL 630 (e.g., conductive pad 705-d).

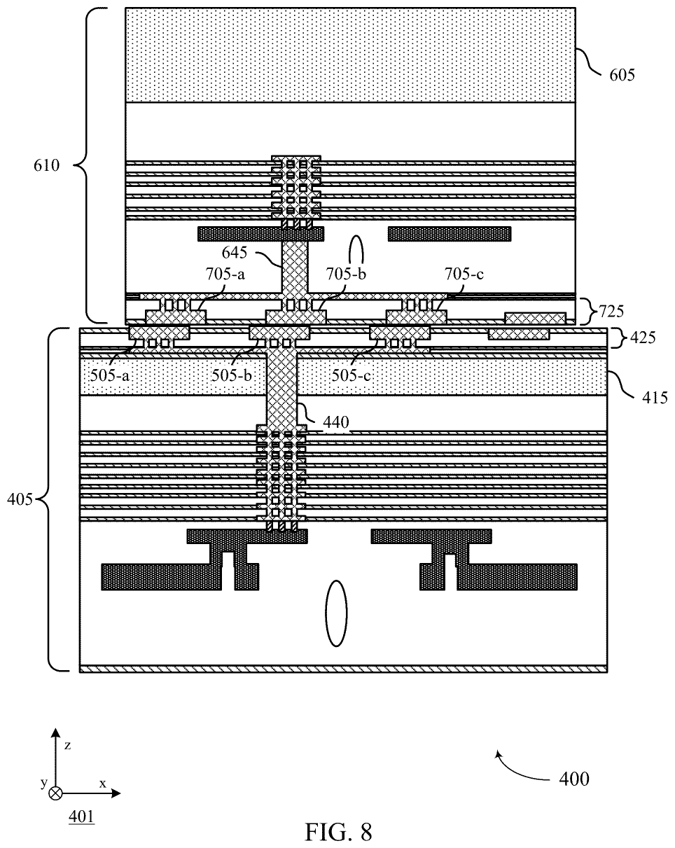

FIG. 8 shows an example of a semiconductor device 400 after a fifth set of one or more manufacturing operations. For example, the fifth set of operations may include bonding (e.g., hybrid bonding, C2W bonding) the memory chip 610 with the die 405. The bonding may be based on the conductive pads 505 (e.g., functional conductive pads) of the die 405 and the conductive pads 705 (e.g., functional conductive pads) of the memory chip 610. In some examples, the bonding may be performed based on a C2W bonding procedure in which the memory chip 610 may have been diced from a wafer of memory chips 610 prior to the bonding. That is, bonding the die 405 to the memory chip 610 may be based on (e.g., after) a dicing of the memory chip 610 from a wafer. In some examples, the memory chip 610 may also have satisfied a performance evaluation prior to the bonding (e.g., the memory chip 610 may be a known-good-die). Additionally, in accordance with the C2W bonding, the die 405 may be part of a wafer that includes multiple dies 405 (not shown).

Accordingly, the redundant conductive pads 505 and 705 may provide alternate electrical paths, which may increase a reliability of the semiconductor device 400. That is, a bond between a pad 505 and a pad 705 may be faulty and the semiconductor device 400 may still satisfy a performance evaluation (e.g., avoid being rejected) based on one or more redundant bonds. Additionally, the redundant conductive pads 505 and 705 may reduce a resistance (e.g., a current density) associated with the bond between the die 405 and the memory chip 610, further improving reliability of the bonded connection (e.g., extend a life of the bond). Thus, a semiconductor device 400 may be manufactured with increased efficiency, increased reliability, providing benefits for production and performance of the semiconductor device 400.

Although described with reference to a 1:1 memory system configuration where one memory chip 610 is coupled with one die 405, the techniques described herein may be implemented in other memory system configurations, such as a 4:1 configuration, a 4:2 configuration, a 2:2 configuration, a 8:1 configuration, a 12:1 configuration, a 16:1 configuration and so on, where an n:N configuration refers to a configuration with n memory chips 610 and N dies 405. In some examples (e.g., in 3D stacked memory stacked memory systems), there may be multiple (e.g., 4, 6, 8) n:N configuration stacks (e.g., 8:1 configuration, 12:1 configuration, 16:1 configuration) on a processor (e.g., a CPU, a GPU). For instance, in some implementations, the semiconductor device 400 may include a stack of multiple memory chips 610 (e.g., more than one memory chip 610, at least 4, 8, 12, or 16 memory dies). Moreover, although some of the described techniques are described in the context of memory systems, the techniques described herein may be implemented in other semiconductor systems that implement heterogeneous semiconductor components (e.g., dies associated with different functions, including different logic functions, different storage or processing functions, or any combination thereof), including heterogeneous semiconductor components that are interconnected within a layer, between layers, or any combination thereof.

FIG. 9 shows an example of a semiconductor device 900 that supports redundant bond pads in stacked semiconductor architectures in accordance with examples as disclosed herein. The semiconductor device 900 may support a redundancy scheme that is based on one or more redundant vias (e.g., addition, or alternate, to an RDL coupled with redundant conductive pads). The semiconductor device 900 may include a die 405-a and a memory chip 610-a, which may be respective examples of, and include similar structures as, a die 405 and a memory chip 610, as described with reference to FIGS. 4 through 8. In some examples, to form a semiconductor device 900 a manufacturing system may perform several manufacturing operations.

A first set of manufacturing operations may be associated with forming the memory chip 610-a. For example, the first set of operations may include forming a memory chip 610-a that includes various layers of one or more dielectric materials 615, one or more dielectric materials 620, and a substrate material 605. The memory chip 610-a may further be formed to include a via 645 and a via 910 (e.g., a redundant via). The via 645 and the via 910 may be coupled with circuitry 650 of the memory chip 610-a. The first set of operations may include forming multiple conductive pads 915 at a surface of the memory chip that is opposite a substrate material 605 of the memory chip 610-a (e.g., a frontside, frontside hybrid bond pads). The via 645 and the via 910 may be coupled with respective conductive pads 915 (e.g., the via 645 may be coupled with a conductive pad 915-b and the via 910 may be coupled with a conductive pad 915-c). In some examples, the first set of operations may include dicing, after forming multiple conductive pads 915, the memory chip 610-a from a wafer that includes multiple memory chips 610. Additionally, the memory chip 610-a may include at least some conductive pads 915 that are not coupled with a via (e.g., conductive pads 915-a and 915-d).

The via 645 and the via 910 may extend from the multiple conductive pads 915 through a dielectric material 615 (e.g., an oxide material) of the memory chip 610-a (e.g., the vias 645 and 910 may be TOVs). The via 645 may be coupled with the circuitry 650 of the memory chip 610-a based on an aluminum contact 655-a associated with the circuitry 650 and the via 910 may be coupled with the circuitry 650 of the memory chip 610-a based on an aluminum contact 655-b associated with the circuitry 650.

A second set of manufacturing operations may be associated with forming the die 405-a. For example, the second set of operations may include forming a die 405-a that includes various layers of one or more dielectric materials 410, one or more dielectric materials 420, and a substrate material 415. The die 405-a may further be formed to include a via 440 and a via 905 (e.g., a redundant via). The via 440 and the via 905 may be coupled with circuitry 445 of the die 405-a. The second set of operations may include forming multiple conductive pads 920 at a surface of the die 405-a that on a same side as a substrate material 415 of the die 405-a (e.g., a backside, backside hybrid bond pads). The via 440 and the via 905 may be coupled with respective conductive pads 920 (e.g., the via 440 may be coupled with a conductive pad 920-b and the via 905 may be coupled with a conductive pad 920-c). Additionally, the die 405-a may include at least some conductive pads 920 that are not coupled with a via (e.g., conductive pads 920-a and 920-d).

The via 440 and the via 905 may extend from the multiple conductive pads 920 through a substrate material 415 (e.g., a silicon material) of the die 405-a (e.g., the vias 440 and 905 may be TSVs). The via 440 may be coupled with RDL materials 450-a (e.g., aluminum iRDL) within the die 405-a, and the via 905 may be coupled with RDL materials 450-b (e.g., aluminum iRDL) within the die 405.

A third set of manufacturing operations may include bonding the memory chip 610-a with the die 405-a based on the conductive pads 915 and the conductive pads 920. In some examples, the bonding may be performed based on a C2W bonding procedure in which the memory chip 610-a may have been diced from a wafer of memory chips 610 prior to the bonding. That is, bonding the die 405-a to the memory chip 610-a may be based on (e.g., after) a dicing of the memory chip 610-a from a wafer. In some examples, the memory chip 610-a may also have satisfied a performance evaluation prior to the bonding (e.g., the memory chip 610-a may be a known-good-die). Additionally, in accordance with the C2W bonding, the die 405-a may be part of a wafer that includes multiple dies 405 (not shown).

Accordingly, the redundant vias 905 and 910 may provide alternate electrical paths, which may increase a reliability of the semiconductor device 900 (e.g., the vias 905 and 910 may support a same give path as the vias 440 and 645). That is, the redundant vias 905 and 910 may repurpose one or more redundant conductive pads 915 and 920 (e.g., pad 915-c and pad 920-c) to support an alternate electrical path to the circuitry 445 and the circuitry 650. That is, a bond between a pad 915 and a pad 920 may be faulty and the semiconductor device 900 may still satisfy a performance evaluation (e.g., avoid being rejected) based on one or more redundant via paths. Additionally, the redundant vias 905 and 910 may reduce a resistance (e.g., a current density) associated with the bond between the die 405-a and the memory chip 610-a, further improving reliability of the bonded connection (e.g., extend a life of the bond). Thus, a semiconductor device 900 may be manufactured with increased efficiency, increased reliability, providing benefits for production and performance of the semiconductor device 900.

Although described with reference to a 1:1 memory system configuration where one memory chip 610-a is coupled with one die 405-a, the techniques described herein may be implemented in other memory system configurations, such as a 4:1 configuration, a 4:2 configuration, a 2:2 configuration, a 8:1 configuration, a 12:1 configuration, a 16:1 configuration and so on, where an n:N configuration refers to a configuration with n memory chips 610-a and N dies 405-a. In some examples (e.g., in 3D stacked memory stacked memory systems), there may be multiple (e.g., 4, 6, 8) n:N configuration stacks (e.g., 8:1 configuration, 12:1 configuration, 16:1 configuration) on a processor (e.g., a CPU, a GPU). For instance, in some implementations, the semiconductor device 900 may include a stack of multiple memory chips 610-a (e.g., more than one memory chip 610-a, at least 4, 8, 12, or 16 memory dies). Moreover, although some of the described techniques are described in the context of memory systems, the techniques described herein may be implemented in other semiconductor systems that implement heterogeneous semiconductor components (e.g., dies associated with different functions, including different logic functions, different storage or processing functions, or any combination thereof), including heterogeneous semiconductor components that are interconnected within a layer, between layers, or any combination thereof.

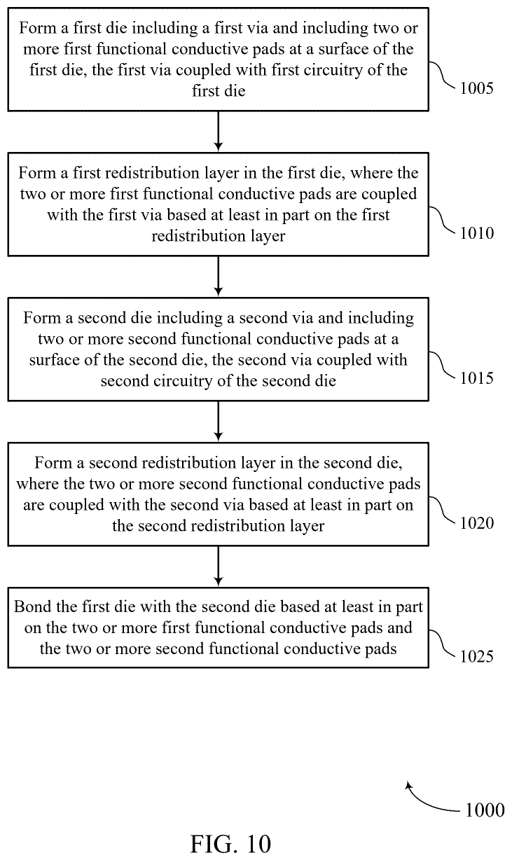

FIG. 10 shows a flowchart illustrating a method 1000 that supports redundant bond pads in stacked semiconductor architectures in accordance with examples as disclosed herein. The operations of method 1000 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1005, the method may include forming a first die including a first via and including two or more first functional conductive pads at a surface of the first die, the first via coupled with first circuitry of the first die.

At 1010, the method may include forming a first RDL in the first die, where the two or more first functional conductive pads are coupled with the first via based at least in part on the first RDL.

At 1015, the method may include forming a second die including a second via and including two or more second functional conductive pads at a surface of the second die, the second via coupled with second circuitry of the second die.

At 1020, the method may include forming a second RDL in the second die, where the two or more second functional conductive pads are coupled with the second via based at least in part on the second RDL.

At 1025, the method may include bonding the first die with the second die based at least in part on the two or more first functional conductive pads and the two or more second functional conductive pads.

In some examples, an apparatus as described herein may perform a method or methods, such as the method 1000. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a first die including a first via and including two or more first functional conductive pads at a surface of the first die, the first via coupled with first circuitry of the first die; forming a first redistribution layer in the first die, where the two or more first functional conductive pads are coupled with the first via based at least in part on the first redistribution layer; forming a second die including a second via and including two or more second functional conductive pads at a surface of the second die, the second via coupled with second circuitry of the second die; forming a second redistribution layer in the second die, where the two or more second functional conductive pads are coupled with the second via based at least in part on the second redistribution layer; and bonding the first die with the second die based at least in part on the two or more first functional conductive pads and the two or more second functional conductive pads.

Aspect 2: The method or apparatus of aspect 1, further including operations, features, circuitry, logic, means, or instructions, or any combination thereof for forming a plurality of third vias in a dielectric layer positioned over the second redistribution layer and forming the two or more second functional conductive pads over the dielectric layer, where each second functional conductive pad of the two or more second functional conductive pads is coupled with a respective subset of third vias of the plurality of third vias, and where the two or more second functional conductive pads are coupled with the second via based at least in part on the plurality of third vias.

Aspect 3: The method or apparatus of any of aspects 1 through 2, further including operations, features, circuitry, logic, means, or instructions, or any combination thereof for forming a plurality of third vias in a dielectric layer positioned over the first redistribution layer and forming the two or more first functional conductive pads over the dielectric layer, where each first functional conductive pad of the two or more first functional conductive pads is coupled with a respective subset of third vias of the plurality of third vias, and where the two or more first functional conductive pads are coupled with the first via based at least in part on the plurality of third vias.

Aspect 4: The method or apparatus of any of aspects 1 through 3, where forming the first die includes operations, features, circuitry, logic, means, or instructions, or any combination thereof for dicing, after forming the first redistribution layer, the first die from a wafer including a plurality of first dies including the first die, where bonding the first die with the second die is based at least in part on the dicing.

Aspect 5: The method or apparatus of any of aspects 1 through 4, where the first via extends from the first redistribution layer through an oxide material of the first die.

Aspect 6: The method or apparatus of any of aspects 1 through 5, where the second via extends from the second redistribution layer through a silicon material of the second die.

Aspect 7: The method or apparatus of any of aspects 1 through 6, where the first via is coupled with the first circuitry of the first die based at least in part on an aluminum contact of the first circuitry.

Aspect 8: The method or apparatus of any of aspects 1 through 7, where the second via is coupled with one or more redistribution layer materials within the second die based at least in part on the second circuitry of the second die.

Aspect 9: The method or apparatus of any of aspects 1 through 8, where forming the first redistribution layer includes operations, features, circuitry, logic, means, or instructions, or any combination thereof for forming the first redistribution layer on a side of the first die that is opposite a substrate of the first die.

Aspect 10: The method or apparatus of any of aspects 1 through 9, where forming the second redistribution layer includes operations, features, circuitry, logic, means, or instructions, or any combination thereof for forming the second redistribution layer on a same side of the second die as a substrate of the second die.

Aspect 11: The method or apparatus of aspects 1 through 10, where the second die is part of a wafer of a plurality of second dies including the second die and bonding the first die with the second die is based at least in part on a chip-to-wafer bonding procedure.

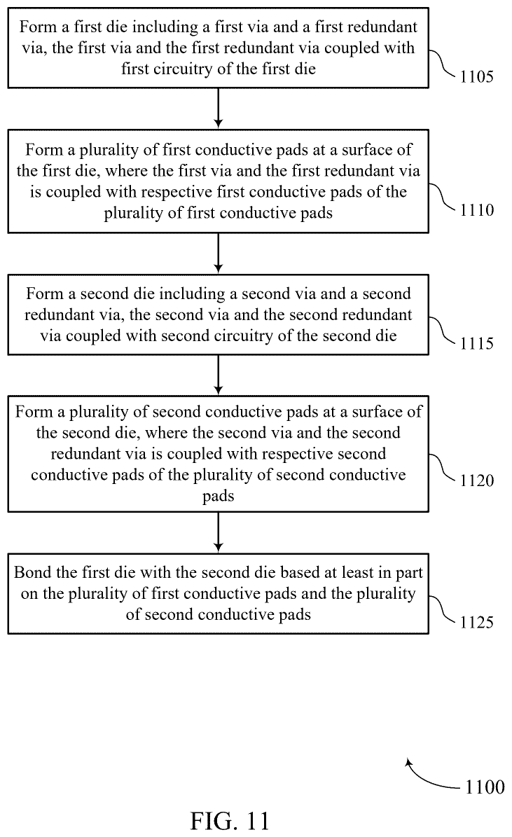

FIG. 11 shows a flowchart illustrating a method 1100 that supports redundant bond pads in stacked semiconductor architectures in accordance with examples as disclosed herein. The operations of method 1100 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1105, the method may include forming a first die including a first via and a first redundant via, the first via and the first redundant via coupled with first circuitry of the first die.

At 1110, the method may include forming a plurality of first conductive pads at a surface of the first die, where the first via and the first redundant via are coupled with respective first conductive pads of the plurality of first conductive pads.

At 1115, the method may include forming a second die including a second via and a second redundant via, the second via and the second redundant via coupled with second circuitry of the second die.

At 1120, the method may include forming a plurality of second conductive pads at a surface of the second die, where the second via and the second redundant via is coupled with respective second conductive pads of the plurality of second conductive pads.

At 1125, the method may include bonding the first die with the second die based at least in part on the plurality of first conductive pads and the plurality of second conductive pads.

In some examples, an apparatus as described herein may perform a method or methods, such as the method 1100. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 12: A method or apparatus including operations, features, circuitry, logic, means, or instructions, or any combination thereof for forming a first die including a first via and a first redundant via, the first via and the first redundant via coupled with first circuitry of the first die; forming a plurality of first conductive pads at a surface of the first die, where the first via and the first redundant via are coupled with respective first conductive pads of the plurality of first conductive pads; forming a second die including a second via and a second redundant via, the second via and the second redundant via coupled with second circuitry of the second die; forming a plurality of second conductive pads at a surface of the second die, where the second via and the second redundant via is coupled with respective second conductive pads of the plurality of second conductive pads; and bonding the first die with the second die based at least in part on the plurality of first conductive pads and the plurality of second conductive pads.

Aspect 13: The method or apparatus of aspect 12, where forming the first die includes operations, features, circuitry, logic, means, or instructions, or any combination thereof for dicing, after forming the plurality of first conductive pads, the first die from a wafer including a plurality of first dies including the first die, where bonding the first die with the second die is based at least in part on the dicing.

Aspect 14: The m method or apparatus of any of aspects 12 through 13, where the first via and the first redundant via extend from the plurality of first conductive pads through an oxide material of the first die.

Aspect 15: The method, apparatus, or non-transitory computer-readable medium of any of aspects 12 through 14, where the second via and the second redundant via extends from the plurality of second conductive pads through a silicon material of the second die.

Aspect 16: The method or apparatus of any of aspects 12 through 15, where the first via is coupled with the first circuitry of the first die based at least in part on a first aluminum contact of the first circuitry and the first redundant via is coupled with the first circuitry of the first die based at least in part on a second aluminum contact of the first circuitry.

Aspect 17: The method or apparatus of any of aspects 12 through 16, where the second via is coupled with one or more first redistribution layer materials within the second die and the second redundant via is coupled with one or more second redistribution layer materials within the second die.

Aspect 18: The method or apparatus of any of aspects 12 through 17, where forming the plurality of first conductive pads includes operations, features, circuitry, logic, means, or instructions, or any combination thereof for forming the plurality of first conductive pads on a side of the first die that is opposite a substrate of the first die.

Aspect 19: The method or apparatus of any of aspects 12 through 18, where forming the plurality of second conductive pads includes operations, features, circuitry, logic, means, or instructions, or any combination thereof for forming the plurality of second conductive pads on a same side of the second die as a substrate of the second die.

Aspect 20: The method or apparatus of any of aspects 12 through 19, where the second die is part of a wafer of a plurality of second dies including the second die and bonding the first die with the second die is based at least in part on a chip-to-wafer bonding procedure.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 21: A semiconductor device, including: a first die including: a first via; first circuitry coupled with the first via; two or more first functional conductive pads at a surface of the first die; and a first redistribution layer that couples the two or more first functional conductive pads with the first via; and a second die including: a second via; second circuitry coupled with the second via; two or more second functional conductive pads at a surface of the second die; and a second redistribution layer in the second die that couples the two or more second functional conductive pads with the second via.

Aspect 22: The semiconductor device of aspect 21, where the second die further includes: a plurality of third vias included in a dielectric layer positioned over the second redistribution layer, where each second functional conductive pad of the two or more second functional conductive pads is coupled with a respective subset of third vias of the plurality of third vias, and where the two or more second functional conductive pads are coupled with the second via based at least in part on the plurality of third vias.

Aspect 23: The semiconductor device of any of aspects 21 through 22, where the first die further includes: a plurality of third vias included in a dielectric layer positioned over the first redistribution layer, where each first functional conductive pad of the two or more first functional conductive pads is coupled with a respective subset of third vias of the plurality of third vias, and where the two or more first functional conductive pads are coupled with the first via based at least in part on the plurality of third vias.

Aspect 24: The semiconductor device of any of aspects 21 through 23, where the first via extends from the first redistribution layer through an oxide material of the first die.

Aspect 25: The semiconductor device of any of aspects 21 through 24, where the second via extends from the second redistribution layer through a silicon material of the second die.

Aspect 26: The semiconductor device of any of aspects 21 through 25, where the first via is coupled with the first circuitry of the first die based at least in part on an aluminum contact of the first circuitry.

Aspect 27: The semiconductor device of any of aspects 21 through 26, where the second via is coupled with one or more redistribution layer materials within the second die based at least in part on the second circuitry of the second die.

Aspect 28: The semiconductor device of any of aspects 21 through 27, where the first die further includes: a substrate material, where the first redistribution layer is positioned on a side of the first die that is opposite the substrate material.

Aspect 29: The semiconductor device of any of aspects 21 through 28, where the second die further includes: a substrate material, where the second redistribution layer is positioned on a same side of the second die as the substrate material.

Aspect 30: The semiconductor device of any of aspects 21 through 29, where the two or more first functional conductive pads are coupled with the two or more second functional conductive pads.

Aspect 31: The semiconductor device of any of aspects 21 through 30, where the first die is a different type of die than the second die.

Aspect 32: The semiconductor device of any of aspects 21 through 31, where the first die is a same type of die as the second die.

Aspect 33: The semiconductor device of any of aspects 21 through 32, where the first die is one of a plurality of first dies included in a stack of first dies.

An apparatus is described. The following provides an overview of aspects of the apparatus as described herein:

Aspect 30: A semiconductor device, including: a first die including: a first via; a first redundant via; first circuitry coupled with the first via and the first redundant via; and a plurality of first conductive pads at a surface of the first die where the first via and the first redundant via are coupled with respective first conductive pads of the plurality of first conductive pads; and a second die including: a second via; a second redundant via; second circuitry coupled with the second via and the second redundant via; and a plurality of second conductive pads at a surface of the second die, where the second via and the second redundant via is coupled with respective second conductive pads of the plurality of second conductive pads.

Aspect 31: The semiconductor device of aspect 30, where the first via and the first redundant via extend from the plurality of first conductive pads through an oxide material of the first die.

Aspect 32: The semiconductor device of any of aspects 30 through 31, where the second via and the second redundant via extends from the plurality of second conductive pads through a silicon material of the second die.

Aspect 33: The semiconductor device of any of aspects 30 through 32, where the second circuitry includes one or more first redistribution layer materials and one or more second redistribution layer materials, and the second via is coupled with the one or more first redistribution layer materials and the second redundant via is coupled with the one or more second redistribution layer materials.

Aspect 34: The semiconductor device of any of aspects 30 through 33, where the second circuitry includes one or more first redistribution layer materials and one or more second redistribution layer materials, and the second via is coupled with the one or more first redistribution layer materials and the second redundant via is coupled with the one or more second redistribution layer materials.

Aspect 35: The semiconductor device of any of aspects 30 through 34, where the first die further includes: a substrate material, where the plurality of first conductive pads are positioned on a side of the first die that is opposite the substrate material.

Aspect 36: The semiconductor device of any of aspects 30 through 35, where the second die includes: a substrate material, where the plurality of second conductive pads are positioned on a same side of the second die as the substrate material.

An apparatus is described. The following provides an overview of aspects of the apparatus as described herein:

Aspect 37: A memory device, including: a first via coupled with first circuitry of the memory device, the first circuitry operable to perform one or more access operations at the memory device; two or more functional conductive pads at a surface of the memory device; and a first redistribution layer, where the two or more functional conductive pads are coupled with the first via based at least in part on the first redistribution layer.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor device, comprising:
a first die comprising:
a first via;
first circuitry coupled with the first via;
two or more first functional conductive pads at a surface of the first die; and
a first redistribution layer that couples the two or more first functional conductive pads with the first via; and
a second die comprising:
a second via;
second circuitry coupled with the second via;
two or more second functional conductive pads at a surface of the second die; and
a second redistribution layer in the second die that couples the two or more second functional conductive pads with the second via.

2. The semiconductor device of claim 1, wherein the second die further comprises:
a plurality of third vias included in a dielectric layer positioned over the second redistribution layer, wherein each second functional conductive pad of the two or more second functional conductive pads is coupled with a respective subset of third vias of the plurality of third vias, and wherein the two or more second functional conductive pads are coupled with the second via based at least in part on the plurality of third vias.

3. The semiconductor device of claim 1, wherein the first die further comprises:
a plurality of third vias included in a dielectric layer positioned over the first redistribution layer, wherein each first functional conductive pad of the two or more first functional conductive pads is coupled with a respective subset of third vias of the plurality of third vias, and wherein the two or more first functional conductive pads are coupled with the first via based at least in part on the plurality of third vias.

4. The semiconductor device of claim 1, wherein the first via extends from the first redistribution layer through an oxide material of the first die.

5. The semiconductor device of claim 1, wherein the second via extends from the second redistribution layer through a silicon material of the second die.

6. The semiconductor device of claim 1, wherein the first via is coupled with the first circuitry of the first die based at least in part on an aluminum contact of the first circuitry.

7. The semiconductor device of claim 1, wherein the second via is coupled with one or more redistribution layer materials within the second die based at least in part on the second circuitry of the second die.

8. The semiconductor device of claim 1, wherein:
the first die further comprises a substrate material, wherein the first redistribution layer is positioned on a side of the first die that is opposite the substrate material; and
the second die further comprises a substrate material, wherein the second redistribution layer is positioned on a same side of the second die as the substrate material.

9. The semiconductor device of claim 1, wherein the two or more first functional conductive pads are coupled with the two or more second functional conductive pads.

10. The semiconductor device of claim 1, wherein the first die is a different type of die than the second die.

11. A method of manufacturing a semiconductor device, comprising:
forming a first die comprising a first via and comprising two or more first functional conductive pads at a surface of the first die, the first via coupled with first circuitry of the first die;
forming a first redistribution layer in the first die, wherein the two or more first functional conductive pads are coupled with the first via based at least in part on the first redistribution layer;
forming a second die comprising a second via and comprising two or more second functional conductive pads at a surface of the second die, the second via coupled with second circuitry of the second die;
forming a second redistribution layer in the second die, wherein the two or more second functional conductive pads are coupled with the second via based at least in part on the second redistribution layer; and
bonding the first die with the second die based at least in part on the two or more first functional conductive pads and the two or more second functional conductive pads.

12. The method of claim 11, further comprising:
forming a plurality of third vias in a dielectric layer positioned over the second redistribution layer; and
forming the two or more second functional conductive pads over the dielectric layer, wherein each second functional conductive pad of the two or more second functional conductive pads is coupled with a respective subset of third vias of the plurality of third vias, and wherein the two or more second functional conductive pads are coupled with the second via based at least in part on the plurality of third vias.

13. The method of claim 11, further comprising:
forming a plurality of third vias in a dielectric layer positioned over the first redistribution layer; and
forming the two or more first functional conductive pads over the dielectric layer, wherein each first functional conductive pad of the two or more first functional conductive pads is coupled with a respective subset of third vias of the plurality of third vias, and wherein the two or more first functional conductive pads are coupled with the first via based at least in part on the plurality of third vias.

14. The method of claim 11, wherein forming the first die comprises:
dicing, after forming the first redistribution layer, the first die from a wafer comprising a plurality of first dies including the first die, wherein bonding the first die with the second die is based at least in part on the dicing.

15. The method of claim 11, wherein the first via extends from the first redistribution layer through an oxide material of the first die.

16. The method of claim 11, wherein the second via is coupled with one or more redistribution layer materials within the second die based at least in part on the second circuitry of the second die.

17. The method of claim 11, wherein:
forming the first redistribution layer comprises forming the first redistribution layer on a side of the first die that is opposite a substrate of the first die; and
forming the second redistribution layer comprises forming the second redistribution layer on a same side of the second die as a substrate of the second die.

18. The method of claim 11, wherein:
the second die is part of a wafer of a plurality of second dies including the second die; and
bonding the first die with the second die is based at least in part on a chip-to-wafer bonding procedure.

19. A semiconductor device, comprising:
a first die comprising:
a first via;
a first redundant via;
first circuitry coupled with the first via and the first redundant via; and
a plurality of first conductive pads at a surface of the first die wherein the first via and the first redundant via are coupled with respective first conductive pads of the plurality of first conductive pads; and
a second die comprising:
a second via;
a second redundant via;
second circuitry coupled with the second via and the second redundant via; and
a plurality of second conductive pads at a surface of the second die, wherein the second via and the second redundant via is coupled with respective second conductive pads of the plurality of second conductive pads.

20. The semiconductor device of claim 19, wherein the first via and the first redundant via extend from the plurality of first conductive pads through an oxide material of the first die.

21. The semiconductor device of claim 19, wherein the second via and the second redundant via extends from the plurality of second conductive pads through a silicon material of the second die.

22. The semiconductor device of claim 19, wherein the first circuitry comprises a first aluminum contact and a second aluminum contact, and the first via is coupled with the first aluminum contact and the first redundant via is coupled with the second aluminum contact.

23. The semiconductor device of claim 19, wherein the second circuitry comprises one or more first redistribution layer materials and one or more second redistribution layer materials, and wherein the second via is coupled with the one or more first redistribution layer materials and the second redundant via is coupled with the one or more second redistribution layer materials.

24. The semiconductor device of claim 19, wherein the first die further comprises:
a substrate material, wherein the plurality of first conductive pads are positioned on a side of the first die that is opposite the substrate material.

25. The semiconductor device of claim 19, wherein the second die comprises:
a substrate material, wherein the plurality of second conductive pads are positioned on a same side of the second die as the substrate material.

26. A method of manufacturing a semiconductor device, comprising:
forming a first die comprising a first via and a first redundant via, the first via and the first redundant via coupled with first circuitry of the first die;
forming a plurality of first conductive pads at a surface of the first die, wherein the first via and the first redundant via are coupled with respective first conductive pads of the plurality of first conductive pads;
forming a second die comprising a second via and a second redundant via, the second via and the second redundant via coupled with second circuitry of the second die;
forming a plurality of second conductive pads at a surface of the second die, wherein the second via and the second redundant via is coupled with respective second conductive pads of the plurality of second conductive pads; and
bonding the first die with the second die based at least in part on the plurality of first conductive pads and the plurality of second conductive pads.

27. The method of claim 26, wherein forming the first die comprises:
dicing, after forming the plurality of first conductive pads, the first die from a wafer comprising a plurality of first dies including the first die, wherein bonding the first die with the second die is based at least in part on the dicing.

28. The method of claim 26, wherein the first via and the first redundant via extend from the plurality of first conductive pads through an oxide material of the first die.

29. The method of claim 26, wherein the second via and the second redundant via extends from the plurality of second conductive pads through a silicon material of the second die.

30. The method of claim 26, wherein the first via is coupled with the first circuitry of the first die based at least in part on a first aluminum contact of the first circuitry and the first redundant via is coupled with the first circuitry of the first die based at least in part on a second aluminum contact of the first circuitry.
